(19) United States
(12) Patent Application Publication
(10) Pub. No.: US 2009/0191712 A1
(43) Pub. Date: Jul. 30, 2009

(54) MANUFACTURING METHOD OF SEMICONDUCTOR DEVICE

(75) Inventors: Kazuyuki HIGASHI, Kanagawa-ken (JP); Takuji Kuniya, Mie-ken (JP); Makoto Wada, Kanagawa-ken (JP); Akihiro Kajita, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/208,010

(22) Filed: Sep. 10, 2008

(30) Foreign Application Priority Data
Sep. 10, 2007 (JP) 2007-233908

(51) Int. Cl. H01L 21/308

(52) U.S. Cl. 438/703; 257/E21.231

(57) ABSTRACT

In one aspect of the present invention, a method of manufacturing a semiconductor device may include forming a first film on an amorphous silicon layer to be patterned, the first film and the amorphous film having a line-and-space ratio of approximately 3:1, sliming down, after processing the first film, a line portion of the pattern from both longitudinal sides of the line portion until the width of the line portion is reduced to approximately one third, reforming a part of the amorphous silicon layer where the first film is not provided such that reformed part has different etching ratio, and removing the first film and the amorphous silicon layer other than reformed part.

### CROSS REFERENCE TO RELATED APPLICATION

This application is based upon and claims the benefit of priority from Japanese Patent Application No. 2007-236177, filed on Sep. 10, 2007, the entire contents of which are incorporated herein by reference.

This application is based upon and claims the benefit of priority from Japanese Patent Application No. 2007-233908, filed on Sep. 10, 2007, the entire contents of which are incorporated herein by reference.

### BACKGROUND

As semiconductor devices have recently been more integrated and improved in performance, patterns for the semiconductor devices have been made finer year by year. Particularly, memory devices, which have been highly integrated, require fine line-and-space patterns, and a lithography technique is being innovated to provide such fine line-and-space patterns. However, demanded degrees of miniaturization are recently exceeding the resolution limitation of lithography. To address the above situation, methods for forming a fine pattern having resolution beyond the limitation are proposed.

One of these methods is a so-called sidewall transfer method, in which films formed on sidewalls in a pattern of a resist or the like are left to be used as parts of the pattern. However, the method has a problem of leaving the films asymmetrically on the sidewalls and thus having difficulty in precisely controlling dimensions of the pattern.

As a method for solving this problem, proposed is a method of repeating formation of a pattern having a line-and-space ratio of 3:1 twice to form a pattern having half the initial line-and-space pitch (see Japanese Patent Application Publication No. 2006-19496, for example). However, this method has a problem of having complicated manufacturing steps.

### SUMMARY

Aspects of the invention relate to an improved manufacturing method of semiconductor device.

In one aspect of the present invention, a method of manufacturing a semiconductor device may include forming a first film on an amorphous silicon layer to be patterned, the first film and the amorphous film having a line-and-space ratio of approximately 3:1, sliming down, after processing the first film, a line portion of the pattern from both longitudinal sides of the line portion until the width of the line portion is reduced to approximately one third, reforming a part of the amorphous silicon layer where the first film is not provided such that reformed part has different etching ratio, and removing the first film and the amorphous silicon layer other than reformed part.

In another aspect of the invention, a method of manufacturing a semiconductor device may include forming a first film on an amorphous silicon layer to be patterned, the first film and the amorphous film having a line-and-space ratio of approximately 3:1, sliming down a line portion of the first film from both longitudinal sides of the line portion until the width of the line portion is reduced to approximately one third, oxidizing an exposed surface of the amorphous silicon layer, removing the first film by using the oxidized amorphous silicon layer as a mask, processing the amorphous silicon layer by using the oxidized amorphous silicon layer as a mask, oxidizing the exposed surface of the amorphous silicon layer such that the exposed surface of the amorphous silicon layer is oxidized.

In another aspect of the invention, a method of manufacturing a semiconductor device may include forming a first film on an amorphous silicon layer to be patterned, the first film and the amorphous silicon layer having a line-and-space ratio of approximately 3:1, reforming a part of the amorphous silicon with the first film provided thereon, such that reformed part has different etching ratio and the ratio of the reformed part to not reformed part is approximately 2:1, and removing the first film and the amorphous silicon layer other than reformed part.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIGS. 1A to 1F are cross-sectional views showing steps of manufacturing a semiconductor device according to a first embodiment of the present invention.

FIGS. 2A to 2H are cross-sectional views showing steps of manufacturing a semiconductor device according to a second embodiment of the present invention.

FIGS. 3A to 3E are cross-sectional views showing steps of manufacturing a semiconductor device according to a third embodiment of the present invention.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

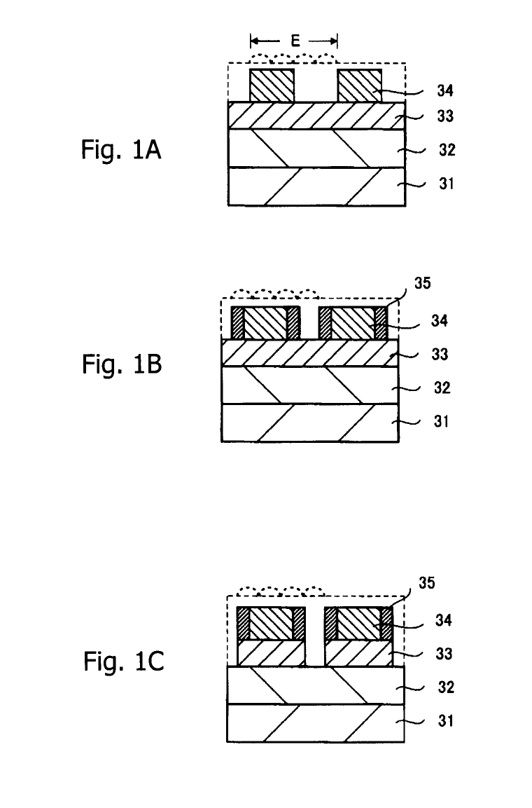

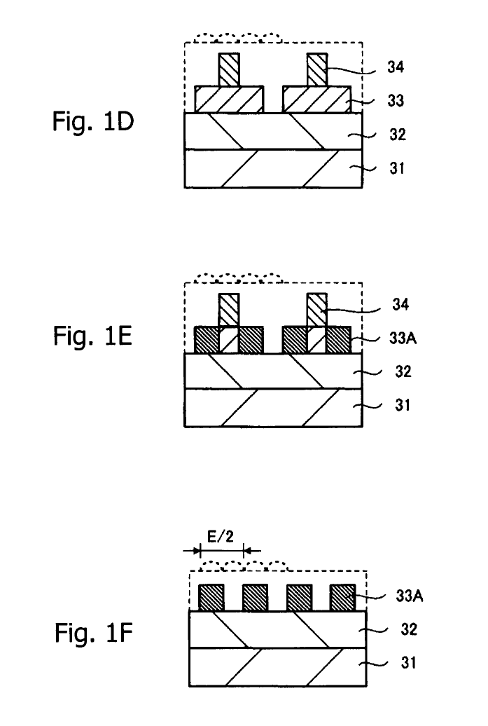

A first embodiment of the present invention will be explained hereinafter with reference to FIGS. 1A-1E.

Hereinafter, description of a third embodiment will be explained. FIGS. 1A to 1F are cross-sectional views showing a method for manufacturing a semiconductor device according to this embodiment.

Firstly, a TEOS film 32 and an amorphous silicon film 33 are sequentially deposited on a semiconductor substrate 31 formed of silicon or the like, by using a technique such as CVD. Then, a resist 34 is deposited thereon by a spin-coat technique, and a line-and-space pattern is formed in the resist 34 by lithography. In this event, a dimensional ratio of each line portion where the resist 34 remains to each space portion where the resist 34 is removed off, that is, a line-and-space ratio, is set to approximately 1:1. A line-and-space pitch, which is the total width of a line portion and a space portion, is represented by E (FIG. 1A). The width of the line portion 34 is E/2, and the width of the space portion between the lines is E/2, as shown in FIG. 1A.

Then, the patterned resist 34 is processed by a resist shrink method so that a reaction layer 35 is formed on each longitudinal side surface of the line portions. Thereby, a dimension of each space portion is reduced to E/4, an approximately half of the initial dimension thereof (FIG. 1B). Note that the patterned resist 34 may be processed by a multilayer resist technique, instead of the resist shrink method. Subsequently, the amorphous silicon film 33 is dry etched by the resist 34 having the reaction layers 35 formed therein as a mask. As a result, a layered pattern consisting of the amorphous silicon film 33 and the resist 34 having the reaction layers 35 formed therein is formed with a line-and-space ratio of approximately 3:1 (FIG. 1C).

Then, the resist 34 having the reaction layers 35 formed therein is dry etched or wet etched so that each line portion thereof can be slimmed down until the resist 34 is caused to have a line-and-space ratio of approximately 1:3. As a result, the dimension of each line portion becomes approximately E/4 (FIG. 1D). Subsequently, portions, not masked with the resist 34, of the amorphous silicon film 33 are reformed by irradiation of ions of an element such as boron, oxygen or nitrogen by an ion implantation method or the like (FIG. 1E). In FIG. 1E, 33A denotes reformed portions of the amorphous silicon film 33, which are reformed by the ion implantation. Subsequently, the resist 34 is removed off by an ashing technique and a wet cleaning technique. Then, unreformed portions of the amorphous silicon film 33 are selectively removed off by using a chemical such as choline so that only the reformed portions 33A are left. As a result, a pattern consisting of the reformed portions 33A of the amorphous silicon film 33 is formed with a line-and-space ratio of approximately 1:1 and with a line-and-space pitch of E/2, an approximately half of the initial pitch E of the resist 34 (FIG. 1F). The width of the line pattern is E/4 and the width of the space is E/4.

This embodiment also includes no processing step of using, as a mask, a fine line pattern having resolution beyond the limitation of lithography. Thus, the embodiment makes it possible to form, with the reformed portions 33A of the amorphous silicon film 33, a pattern having lines of bilaterally symmetric shapes to allow precise dimension control, in a simple way.

Note that examples of an alternative material of the pattern to amorphous silicon includes: metals such as Al, Ti, Co, Ni and the like; and insulating materials such as organic insulating materials, methylsilsesquioxane (MSQ) and hydrogensilsesquioxane (HSQ). When the pattern is formed in a film formed of an insulating material such as an organic insulating material, MSQ or HSQ, the film may be reformed by any method of electron beam irradiation, ultraviolet irradiation and plasma treatment in addition to the above ion implanting method.

### Second Embodiment

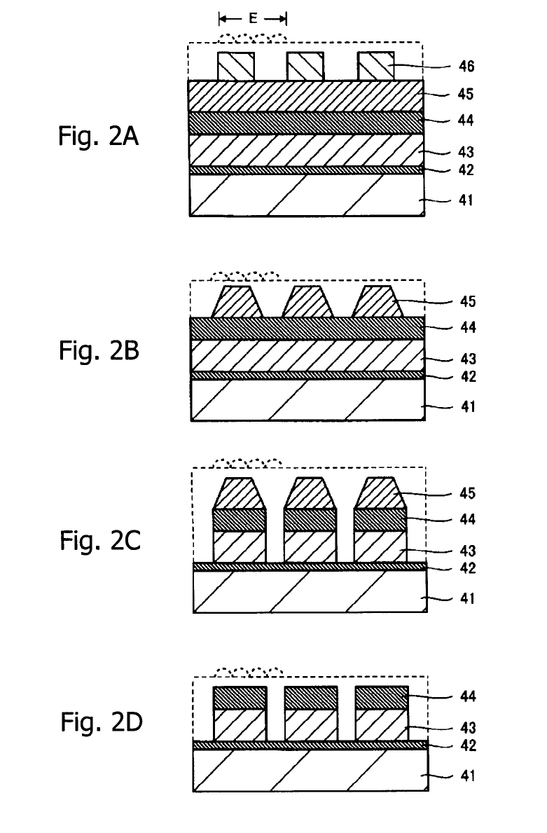

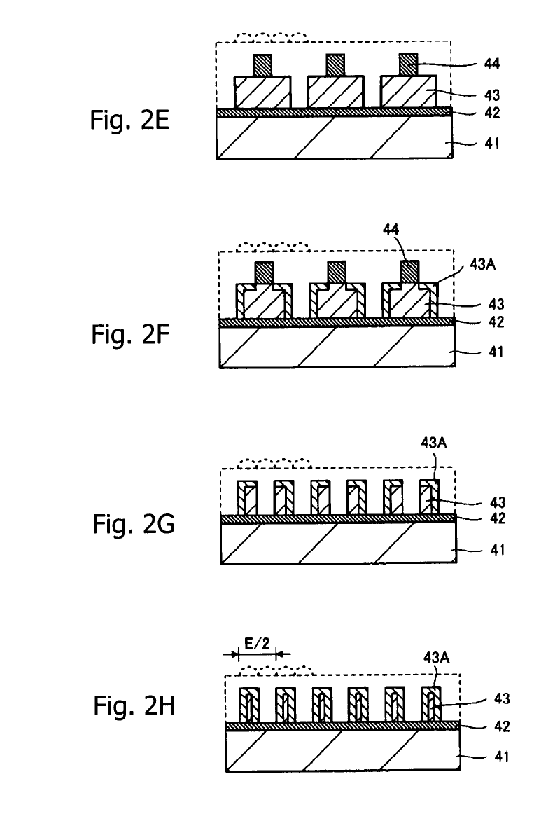

Hereinafter, description of a second embodiment will be explained. FIGS. 2A to 2H are cross-sectional views showing steps of a method for manufacturing a semiconductor device according to this embodiment.

Firstly, a silicon dioxide film 42, an amorphous silicon film 43, a silicon nitride film 44 and a BSG film 45 are sequentially deposited on a semiconductor substrate 41 formed of silicon or the like, by using a technique such as CVD. Then, a resist 46 is stacked thereon by a spin-coat technique, and a line-and-space pattern is formed in the resist 46 by lithography. In this event, a dimensional ratio of line portions where the resist 46 remains to space portions where the resist 46 is removed off, that is, a line-and-space ratio, is set to approximately 1:1. A line-and-space pitch, which is the total width of a line portion and a space portion, is represented by E (FIG. 2A).

Then, the BSG film 45 is dry etched by using the patterned resist 46 as a mask so that each line portion of the BSG film 45 can be tapered, and thereafter the resist 46 is removed off by an ashing technique. In this event, a line-and-space ratio in the bottom of the BSG film 45 is set to approximately 3:1 (FIG. 2B).

Subsequently, the silicon nitride film 44 and the amorphous silicon film 43 are individually and sequentially dry etched by using the BSG film 45 with the tapered pattern as a mask (FIG. 2C), and thereafter the BSG film 45 is removed by wet etching (FIG. 2D). Then, line portions of the silicon nitride film 44 are isotropically etched by wet etching or dry etching so that a pattern of a line-and-space ratio of approximately 1:3 can be formed in the silicon nitride film 44 (FIG. 2E). Surfaces of the amorphous silicon film 43 are then oxidized in an O2 atmosphere or a plasma O2 atmosphere at 800° C. or higher, for example, and, as a result, oxide films 43A are formed (FIG. 2F).

Subsequently, the silicon nitride film 44 is removed by dry etching or wet etching, and thereafter portions, on which no oxide film 43A is formed, of the amorphous silicon film 43 are anisotropically etched off (FIG. 2G). After that, an oxide film 43A is formed also on each etched surface of the amorphous silicon film 43 again in an O2 atmosphere or a plasma O2 atmosphere at 800° C. or higher, for example. This additional formation of the oxide films 43A can improve the bilateral symmetry of the pattern formed in the amorphous silicon film 43. As a result, a pattern is formed in the amorphous silicon film 43 with a line-and-space ratio of approximately 1:1 and with a line-and-space pitch of E/2, an approximately half of the initial pitch E of the resist 46 (FIG. 2H).

This embodiment also includes no processing step of using, as a mask, a fine line pattern having resolution beyond the limitation of lithography. Thus, the embodiment makes it possible to form, in the amorphous silicon film 43, a pattern having lines of bilaterally symmetric shapes to allow precise dimensional control, in a simple way. In addition, this embodiment allows elimination of the following steps as employed in a conventional sidewall transfer method: a sidewall formation step; an etching step required in forming a line-and-space pattern using sidewalls; a post-processing step thereof; and even a CMP step.

### Third Embodiment

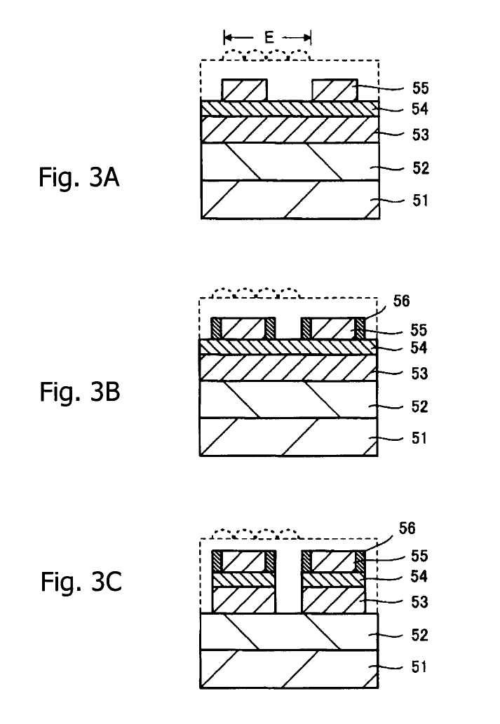

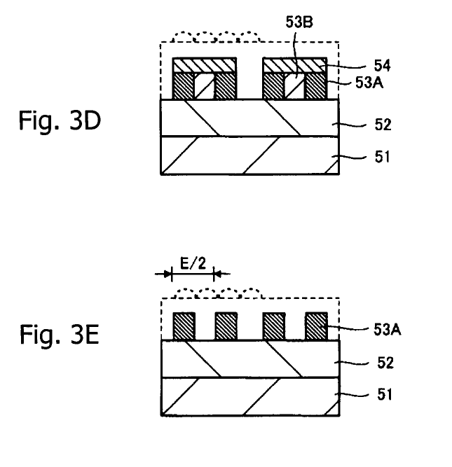

Hereinafter, description of a third embodiment will be explained. FIGS. 3A to 3E are cross-sectional views showing steps of a method for manufacturing a semiconductor device according to this embodiment.

Firstly, a TEOS film 52 and an amorphous silicon film 53 are sequentially deposited on a semiconductor substrate 51 formed of silicon or the like, by using a technique such as CVD. Then, a protective film 54 formed of SiN or the like and a resist 55 are sequentially stacked thereon by a spin-coat technique. Here, the protective film 54 is formed to protect the lower layers from impacts caused by a heat treatment, a plasma treatment and the like. Thereafter, a line-and-space pattern is formed in the resist 55 by lithography. In this event, a dimensional ratio of line portions where the resist 55 remains to space portions where the resist 55 is removed off, that is, a line-and-space ratio, is set to approximately 1:1. A line-and-space pitch, which is the total width of a line portion and a space portion, is represented by E (FIG. 3A).

Then, the patterned resist 55 is processed by a resist shrink method so that a reaction layer 56 is formed on each longitudinal side surface of the line portions. Thereby, a dimension of each space portion is reduced to an approximately half of the original dimension thereof, that is, E/4 (FIG. 3B). Note that the patterned resist 55 may be processed by a multilayer resist technique instead of the resist shrink method. Subsequently, the amorphous silicon film 53 and the protective film 54 are dry etched by using, as a mask, the resist 55 having the reaction layers 56 formed therein. As a result, a layered pattern consisting of the amorphous silicon film 53, the protective film 54 and the resist 55 having the reaction layers 56 formed therein is formed with a line-and-space ratio of approximately 3:1 (FIG. 3C).

Then, the resist 55 is removed together with the reaction layers 56 by an ashing technique and a wet cleaning technique. Thereafter the patterned amorphous silicon film 53 is isotropically heat treated in an atmosphere of a gas such as O2, N2 and NH3 (FIG. 3D) and thereby reformed from the longitudinal sides of line portions thereof. In FIG. 7D, 53A denotes reformed portions of the amorphous silicon film 53, which are reformed by the heat treatment, while 53B denotes unreformed portions of the amorphous silicon film 53. Note that the patterned amorphous silicon film 53 may be reformed by a plasma treatment instead of the heat treatment. The reformation process is preformed such that an unreformed portion 53B in the middle of each line portion and reformed portions 53A on both sides of the unreformed portion 53B can have approximately the same dimension. If the patterned amorphous silicon film 53 is heat treated in an O2 gas atmosphere, the reformed portions 53A are formed of silicon oxide, for example. Subsequently, the protective film 54 and unreformed portions 53B of the amorphous silicon film 53 are selectively removed off by using a chemical such as choline. As a result, a pattern consisting of the reformed portions 53A of the amorphous silicon film 53 is formed with a line-and-space ratio of approximately 1:1 and with a line-and-space pitch of E/2, an approximately half of the initial pitch E of the resist 55 (FIG. 3E).

This embodiment also includes no processing step of using, as a mask, a fine line pattern having resolution beyond the limitation of lithography. Thus, the embodiment makes it possible to form, with the reformed portions 53A of the amorphous silicon film 53, a pattern having lines of bilaterally symmetric shapes to allow precise dimensional control, in a simple way.

In each embodiment described above, the line-and-space ratio of the resist, which is firstly patterned, is set to approximately 1:1, and thereafter the pattern having a line-and-space ratio of approximately 3:1 (the first to fifth embodiments) or approximately 1:3 (the sixth embodiment) is formed. However, the line-and-space ratio of the firstly formed pattern is not limited to approximately 1:1. Moreover, a resist pattern having a line-and-space ratio of approximately 3:1 or approximately 1:3 may be formed by a standard lithography technique, and the resist pattern may be used as a mask pattern for the amorphous silicon film. This can simplify the manufacturing steps even more.

Embodiments of the invention have been described with reference to the examples. However, the invention is not limited thereto.

For example, in one aspect of invention, a method for manufacturing a semiconductor device may include forming, on a first film to be patterned, a pattern having a line-and-space ratio of approximately 3:1, processing the first film by using the pattern as a mask, slimming down, after processing the first film, a line portion of the pattern from both longitudinal sides of the line portion until the width of the line portion is reduced to approximately one third, and thereafter forming a reverse pattern of the slimmed pattern, and reprocessing the processed first film by using the reverse pattern as a mask.

For example, in one aspect of invention, a method for manufacturing a semiconductor device may include forming, on a first film to be patterned, a pattern having a line-and-space ratio of approximately 3:1, processing the first film by using the pattern as a mask, reforming both longitudinal side portions of a line portion of the processed first film, the width of each reformed side portion being approximately one third of that of the line portion, and selectively removing an unreformed portion of the first film.

For example, in one aspect of invention, a method for manufacturing a semiconductor device may include forming, on a first film to be patterned, a film having a pattern of a line-and-space ratio of approximately 1:3 and forming sidewalls on both longitudinal sides of a line portion of the film, the width of each sidewall being approximately the same as that of the line portion, processing the first film by using, as a mask, the film and the sidewalls, filling spaces in the processed first film with a filling material, and selectively removing the film having the pattern of the line-and-space ratio of approximately 1:3, and reprocessing the processed first film by using the sidewalls as a mask.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A method for manufacturing a semiconductor device, comprising:
forming a first film on an amorphous silicon layer to be patterned, the first film and the amorphous film having a line-and-space ratio of approximately 3:1;
sliming down, after processing the first film, a line portion of the pattern from both longitudinal sides of the line portion until the width of the line portion is reduced to approximately one third;
reforming a part of the amorphous silicon layer where the first film is not provided such that reformed part has different etching ratio; and
removing the first film and the amorphous silicon layer other than reformed part.

2. The method of claim 1, wherein reforming the part of the amorphous silicon layer is provided such that the ratio of the reformed part to not reformed part is approximately 2:1.

3. The method of claim 1, wherein forming the first film and the amorphous film having a line-and-space ratio of approximately 3:1 is form includes
forming a first film on an amorphous silicon layer to be patterned, the first film having a line-and-space ratio of approximately 1:1;
increasing a width of the first film such that the first film has a line-and-space ratio of approximately 3:1; and
processing the amorphous silicon layer by using the first film and the sidewalls as a mask.

4. The method of claim 1, wherein forming the first film and the amorphous film having a line-and-space ratio of approximately 3:1 is form includes,
forming a first film on an amorphous silicon layer;
forming a second film on the first film;
forming a third film having a line-and-space ratio of approximately 1:1;
processing the third film by taper etching using the third film as a mask such that second film has a line-and-space ratio of approximately 3:1;
removing the third film; and
processing the first film and the amorphous silicon layer using the second film as a mask.

5. A method for manufacturing a semiconductor device, comprising:
forming a first film on an amorphous silicon layer to be patterned, the first film and the amorphous film having a line-and-space ratio of approximately 3:1;
sliming down a line portion of the first film from both longitudinal sides of the line portion until the width of the line portion is reduced to approximately one third;
oxidizing an exposed surface of the amorphous silicon layer;
removing the first film by using the oxidized amorphous silicon layer as a mask;
processing the amorphous silicon layer by using the oxidized amorphous silicon layer as a mask;
oxidizing the exposed surface of the amorphous silicon layer such that the exposed surface of the amorphous silicon layer is oxidized.

6. The method of claim 5, wherein forming the first film and the amorphous film having a line-and-space ratio of approximately 3:1 is form includes,
forming a first film on an amorphous silicon layer, the first film having a line-and-space ratio of approximately 1:1
increasing a width of the first film such that the first film has a line-and-space ratio of approximately 3:1; and
processing the amorphous silicon layer by using the first film and the sidewalls as a mask.

7. The method of claim 5, wherein forming the first film and the amorphous film having a line-and-space ratio of approximately 3:1 is form includes,
forming a first film on an amorphous silicon layer;
forming a second film on the first film;
forming a third film having a line-and-space ratio of approximately 1:1;
processing the third film by taper etching using the third film as a mask such that second film has a line-and-space ratio of approximately 3:1;
removing the third film; and
processing the first film and the amorphous silicon layer using the second film as a mask.

8. A method for manufacturing a semiconductor device, comprising:
forming a first film on an amorphous silicon layer to be patterned, the first film and the amorphous silicon layer having a line-and-space ratio of approximately 3:1;
reforming a part of the amorphous silicon with the first film provided thereon, such that reformed part has different etching ratio and the ratio of the reformed part to not reformed part is approximately 2:1; and
removing the first film and the amorphous silicon layer other than reformed part.

9. The method of claim 8, wherein forming the first film and the amorphous film having a line-and-space ratio of approximately 3:1 is form includes
forming a first film on an amorphous silicon layer to be patterned, the first film having a line-and-space ratio of approximately 1:1;
increasing a width of the first film such that the first film has a line-and-space ratio of approximately 3:1; and
processing the amorphous silicon layer by using the first film and the sidewalls as a mask.

10. The method of claim 8, wherein forming the first film and the amorphous film having a line-and-space ratio of approximately 3:1 is form includes,
forming a first film on an amorphous silicon layer;
forming a second film on the first film;
forming a third film having a line-and-space ratio of approximately 1:1;
processing the third film by taper etching using the third film as a mask such that second film has a line-and-space ratio of approximately 3:1;
removing the third film; and
processing the first film and the amorphous silicon layer using the second film as a mask.

11. The method of claim 8, wherein forming the first film and the amorphous film having a line-and-space ratio of approximately 3:1 is form includes
forming a first film on an amorphous silicon layer;
forming a second film on the first film, the second film having a; a line-and-space ratio of approximately 1:1;
increasing a width of the second film such that the second film has a line-and-space ratio of approximately 3:1; and
processing the first film and amorphous silicon layer
by using the second film and the sidewalls as a mask.
